(19) United States
(12) Patent Application Publication
(10) Pub. No.: US 2024/0100575 A1
(43) Pub. Date: Mar. 28, 2024

(54) CIRCUIT BOARD CLEANING SYSTEM

(71) Applicant: NAN YA PLASTICS CORPORATION, TAIPEI (TW)

(72) Inventors: TE-CHAO LIAO, TAIPEI (TW); WEI-SHENG CHENG, TAIPEI (TW); CHAO-TUNG WU, TAIPEI (TW)

(21) Appl. No.: 18/079,102

(22) Filed: Dec. 12, 2022

(30) Foreign Application Priority Data
Sep. 26, 2022 (TW) 111136273

(51) Int. Cl. B08B 3/08; B08B 3/12; C11D 1/72; C11D 11/00; C11D 17/00

(52) U.S. Cl. CPC B08B 3/08; B08B 3/12; C11D 1/72; C11D 11/0047; C11D 17/0008; B08B 2203/007

(57) ABSTRACT

A circuit board cleaning system includes a cleaning tank, an ion exchange resin column, and a pump unit. The cleaning tank accommodates a cleaning liquid and allows a circuit board to be immersed in the cleaning liquid. The cleaning liquid includes a liquid water and a hydrocarbon-based surfactant. An ion exchange resin filled in the ion exchange resin column is a basic ion exchange resin. The pump unit is configured to pump the cleaning liquid into the ion exchange resin column, and enable the cleaning liquid to pass through the ion exchange resin column. When the cleaning liquid passes through the ion exchange resin column, the basic ion exchange resin deprotonates the hydrocarbon-based surfactant. After the cleaning liquid passes through the ion exchange resin column, the cleaning liquid is returned to the cleaning tank to remove acidic residue remaining on a surface of the circuit board.

### CROSS-REFERENCE TO RELATED PATENT APPLICATION

This application claims the benefit of priority to Taiwan Patent Application No. 111136273, filed on Sep. 26, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a cleaning system, and more particularly to a circuit board cleaning system, which can clean acidic residues remaining on a circuit board during a manufacturing process of the circuit board.

### BACKGROUND OF THE DISCLOSURE

After a soldering process, a certain amount of flux residue and other contaminants, such as acidic residues, are usually left on a surface of a printed circuit board (PCB). Therefore, a cleaning process for the surface of the circuit board plays an extremely important role in ensuring the reliability of an electronic product that includes the printed circuit board.

In the related art, the cleaning process usually involves using amine compounds and surfactants to clean the acidic residues remaining on the surface of the circuit board. However, after the cleaning process, the amine compounds can easily remain on the surface of the circuit board, resulting in a problem of insufficient stacking adhesion strength in a subsequent process.

Furthermore, the use of the amine compounds requires different formulations for different treatment layers of the circuit board, or otherwise abnormal situations, such as an incomplete cleaning process or an erosion of the treatment layers, may occur. That is, in the related art, a single cleaning formulation cannot be comprehensively applied to the different treatment layers of the circuit board.

### SUMMARY OF THE DISCLOSURE

In response to the above-referenced technical inadequacies, the present disclosure provides a circuit board cleaning system, which can clean acidic residue remaining on the circuit board.

In one aspect, the present disclosure provides a circuit board cleaning system that includes a cleaning tank, an ion exchange resin column, and a pump unit. The cleaning tank is configured to accommodate a cleaning liquid. The cleaning tank allows a circuit board to be immersed in the cleaning liquid during a cleaning process. The cleaning liquid includes a liquid water and a hydrocarbon-based surfactant. The ion exchange resin column is located at a side of the cleaning tank. An ion exchange resin filled in the ion exchange resin column is a basic ion exchange resin. The pump unit is located between the cleaning tank and the ion exchange resin column. The pump unit is configured to pump the cleaning liquid accommodated in the cleaning tank into the ion exchange resin column via a first fluid pipeline, and enable the cleaning liquid to pass through the ion exchange resin column. When the cleaning liquid passes through the ion exchange resin column, the basic ion exchange resin deprotonates the hydrocarbon-based surfactant, and increases a pH value of the cleaning liquid to be between 8 and 11. After the cleaning liquid passes through the ion exchange resin column, the circuit board cleaning system further returns the cleaning liquid to the cleaning tank via a second fluid pipeline, so that the hydrocarbon-based surfactant that is deprotonated is capable of removing an acidic residue remaining on a surface of the circuit board.

In certain embodiments, in the cleaning liquid, the hydrocarbon-based surfactant is a nonionic surfactant. The nonionic surfactant has a chemical structural formula of: R₁—O—[(CH₂CH(R₂)—O)ₓ(CH₂CH₂O)_{y}]_{z}—H, in which x is independently at each occurrence 0 or a real number between about 1 and about 5, provided that at least one occurrence of x is greater than 0; y is independently at each occurrence 0 or a real number between about 1 and about 11, provided that at least one occurrence of y is greater than 0; z is an integer between 1 and 50; R₁ is a branched or straight chain alkyl group having a carbon chain length of C1-C12; and R₂ is independently at each occurrence CH₃ or CH₂CH₃.

In certain embodiments, in the cleaning liquid, the hydrocarbon-based surfactant is diethylene glycol butyl ether, which has a chemical structural formula of: HO(CH₂)₂O(CH₂)₂O(CH₂)₃CH₃.

In certain embodiments, in the cleaning liquid, a content of the hydrocarbon-based surfactant is between 80% (V/V) and 95% (V/V), and a content of the liquid water is between 5% (V/V) and 20% % (V/V).

In certain embodiments, the ion exchange resin filled in the ion exchange resin column is a hydroxide strong basic anion exchange resin.

In certain embodiments, the circuit board cleaning system further includes a pH monitoring unit and a flow rate control unit. The pH monitoring unit is disposed at an outlet end of the ion exchange resin column. The flow rate control unit is disposed on the pump unit. The pH monitoring unit is configured to monitor the pH value of the cleaning liquid that is deprotonated by the ion exchange resin column. The flow rate control unit is able to adjust a flow rate of the cleaning liquid in the first fluid pipeline through the pump unit according to the pH value monitored by the pH monitoring unit, so as to adjust a residence time of the cleaning liquid in the ion exchange resin column.

In certain embodiments, the circuit board cleaning system further includes an ultrasonic vibration unit that is disposed on the cleaning tank. The ultrasonic vibration unit is configured to oscillate the cleaning liquid accommodated in the cleaning tank.

In certain embodiments, the circuit board cleaning system further includes a detection unit. The detection unit is configured to detect an absorption peak of a C═O functional group on the surface of the circuit board. When the detection unit detects that the absorption peak of the C═O functional group on the surface of the circuit board completely disappears or tends to disappear, the circuit board cleaning system determines that the cleaning process to the acidic residue remaining on the surface of the circuit board is completed.

In certain embodiments, the circuit board cleaning system further includes a filter unit, and the filter unit is disposed on the first fluid pipeline that is connected between the cleaning tank and the ion exchange resin column. The filter unit is configured to filter the cleaning liquid from the cleaning tank to remove impurities in the cleaning liquid.

In certain embodiments, a resin filling amount of the ion exchange resin column is that: a column having 120 to 180 cubic centimeters is packed with 50 to 150 grams of the ion exchange resin. A flow rate of the cleaning liquid that passes through the ion exchange resin column is between 0.5 cubic centimeters and 3 cubic centimeters per minute.

Therefore, the circuit board cleaning system of the present disclosure is an innovative cleaning system that includes the basic ion exchange resin, the hydrocarbon-based surfactant, and the liquid water. The circuit board cleaning system of the present disclosure can adjust a cleaning ability by deprotonation of the hydrocarbon-based surfactant through the basic ion exchange resin, thereby cleaning the acidic residue remaining on the surface of the circuit board. Since the cleaning liquid of the circuit board cleaning system does not adopt amine compounds, residual amine compounds will not remain on the surface of the circuit board during the cleaning process, so as to resolve the problem of insufficient stacking adhesion strength caused thereby in subsequent processes.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a circuit board cleaning system according to a first embodiment of the present disclosure;

FIG. 2 is a schematic view of a circuit board cleaning system according to a second embodiment of the present disclosure;

FIG. 3 is a schematic view of a circuit board cleaning system according to a third embodiment of the present disclosure; and

FIG. 4 is a schematic view of a circuit board cleaning system according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

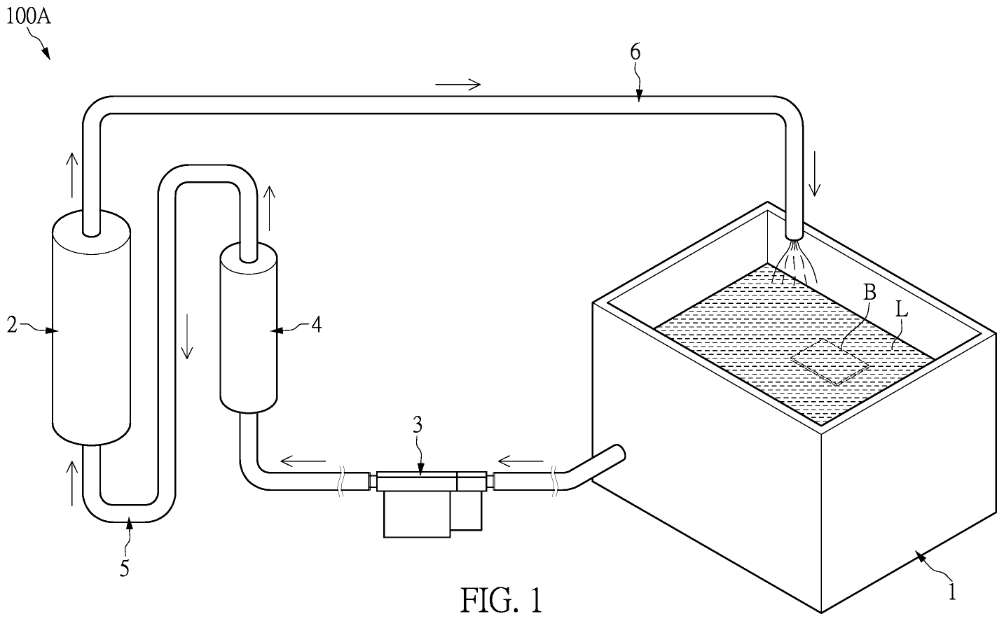

Referring to FIG. 1, a first embodiment of the present disclosure provides a circuit board cleaning system 100A that includes a cleaning tank 1, an ion exchange resin column 2, a pump unit 3, a filter unit 4, a first fluid pipeline 5, and a second fluid pipeline 6.

The cleaning tank 1 is configured to accommodate a cleaning liquid L, and the cleaning tank 1 allows a circuit board B to be immersed in the cleaning liquid L during a cleaning process to clean the circuit board B.

The cleaning liquid L includes liquid water and a surfactant, in which the liquid water is preferably ultrapure water. The ultrapure water is close to high-purity water, i.e., water having almost no other electrolyte except hydrogen ions and hydroxide ions in its composition, but the present disclosure is not limited thereto.

In addition, the surfactant is preferably a hydrocarbon-based surfactant. One end of a chemical structure of the hydrocarbon-based surfactant has a hydrocarbon group (alkyl group), and another end of the chemical structure of the hydrocarbon-based surfactant has a hydroxyl group (—OH).

In an embodiment of the present disclosure, the hydrocarbon-based surfactant is a nonionic surfactant, and a chemical structural formula of the nonionic surfactant is represented by the following formula (I).

R₁—O—[(CH₂CH(R₂)—O)ₓ(CH₂CH₂O)_{y}]_{z}—H (I).

Among them, x is independently at each occurrence 0 or a real number between about 1 and about 5, provided that at least one occurrence of x is greater than 0; y is independently at each occurrence 0 or a real number between about 1 and about 11, provided that at least one occurrence of y is greater than 0; z is an integer between 1 and 50; R₁ is a branched or straight chain alkyl group having a carbon chain length of C1-C12; and R₂ is independently at each occurrence CH₃ or CH₂CH₃.

It should be understood by those skilled in the art that “x” and “y” denote an average degree of propoxylation and/or butoxylation (depending on the type of R2) and an average degree of ethoxylation, respectively. Therefore, x and y may not need to be integers, which are intended to be indicated by the use of “about”. Further, x and y taken together determine a degree of alkoxylation in an oligomer distribution.

It should be understood by those skilled in the art that a configuration of x and y is block or random, in which x is a first and/or a last block. Preferably, PO or BO moiety, and EO moiety are the result of block supply. Similarly, “z” is an integer that represents an iterative operand of the formula.

In an embodiment of the present disclosure, the surfactant is diethylene glycol butyl ether, and the diethylene glycol butyl ether has a chemical structural formula of: HO(CH₂)₂O(CH₂)₂O(CH₂)₃CH₃, which represents a specific embodiment of the above formula (I), but the present disclosure is not limited thereto.

Further, in the cleaning liquid L, a content of the surfactant (especially the hydrocarbon-based surfactant) is preferably between 80% (V/V) and 95% (V/V), and more preferably between 85% (V/V) and 95% (V/V). A content of the liquid water is preferably between 5% (V/V) and 20% (V/V), and more preferably between 5% (V/V) and 15% (V/V). It is worth mentioning that the surfactant can be deprotonated after passing through the ion exchange resin column 2 as described below. The surfactant that is deprotonated can further have an ability to clean acidic residues remaining on the surface of the circuit board B. In addition, the addition of liquid water is used to stabilize the deprotonation process of the surfactant. It is worth mentioning that the “deprotonation” referred to herein is the removal (transfer) of a proton, (H⁺) from a Brønsted-Lowry acid in an acid-base reaction. The species formed is the conjugate base of that acid. The complementary process, when a proton is added (transferred) to a Brønsted-Lowry base, is protonation (or hydronation). The species formed is the conjugate acid of that base.

Referring to FIG. 1 again, the ion exchange resin column 2 is located at a side of the cleaning tank 1. The ion exchange resin column 2 is fluidly connected to the cleaning tank 1 through a first fluid pipeline 5, and the ion exchange resin column 2 is configured to receive the cleaning liquid L from the cleaning tank 1 through the first fluid pipeline 5.

From another perspective, the first fluid pipeline 5 is fluidly connected between an outlet end of the cleaning tank 1 and an inlet end of the ion exchange resin column 2, and the first fluid pipeline 5 is configured to receive the cleaning liquid L from the cleaning tank 1, and transport the cleaning liquid L to the ion exchange resin column 2.

In an embodiment of the present disclosure, an ion exchange resin filled in the ion exchange resin column 2 is a basic ion exchange resin, and is preferably a basic anion exchange resin.

It is worth mentioning that the basic anion exchange resin is an ion exchange resin introduced with an amino active group, which can be exchanged with an anion such as a chloride ion (Cl⁻) or a sulfate ion (SO₄²⁻). According to the basicity of the amino active group, the basic anion exchange resin can be divided into a strong basic anion exchange resin and a weak basic anion exchange resin. An ion exchange resin containing a primary, secondary, tertiary, or quaternary amine group can dissociate with a strong base, such as NaOH and KOH, so that the ion exchange resin is strongly basic, and is generally referred to as a strong basic anion exchange resin.

In some embodiments of the present disclosure, the basic anion exchange resin is preferably a strong basic anion exchange resin, and more preferably a hydroxide type (OH−) strong basic anion exchange resin.

In some embodiments of the present disclosure, the basic anion exchange resin is an anion exchange resin having at least a primary, secondary, tertiary or quaternary amine group on the cross-linked styrene-di-vinyl-benzene backbone. In addition, the basic anion exchange resin does not include halogen, but the present disclosure is not limited thereto.

Further, in an embodiment of the present disclosure, a resin filling amount of the ion exchange resin column 2 is defined by a column having 120 to 180 cubic centimeters (preferably 150 cubic centimeters) being packed with 50 to 150 grams (preferably 100 grams) of the ion exchange resin.

The ion exchange resin column 2 is configured to receive the cleaning liquid L from the cleaning tank 1 through the first fluid pipeline 5, and allows the cleaning liquid L to pass through the ion exchange resin column 2 to perform an ion exchange on the cleaning liquid L.

In some embodiments of the present disclosure, a flow rate of the cleaning liquid L that passes through the ion exchange resin column 2 is between 0.5 cubic centimeters and 3 cubic centimeters per minute, and preferably between 0.8 cubic centimeters and 1.2 cubic centimeters per minute.

The pump unit 3 is disposed on the first fluid pipeline 5 connected between the cleaning tank 1 and the ion exchange resin column 2. The pump unit 3 is configured to pump the cleaning liquid L accommodated in the cleaning tank 1 into the first fluid pipeline 5, and further pump the cleaning liquid L to pass through the ion exchange resin column 2.

Further, the basic ion exchange resin filled in the ion exchange resin column 2 can deprotonate the hydroxyl group (—OH) of the hydrocarbon-based surfactant in the cleaning liquid L, and the basic ion exchange resin can increase a pH value of the cleaning liquid L to be between 8 and 11, and preferably between 8 and 9.

The second fluid pipeline 6 is connected between an outlet end of the ion exchange resin column 2 and an inlet end of the cleaning tank 1. The second fluid pipeline 6 is configured to receive the surfactant that is deprotonated from the ion exchange resin column 2, and return the surfactant to the cleaning tank 1, so as to remove the acidic residues on the surface of the circuit board B.

That is, the surfactant that is deprotonated can be returned to the cleaning tank 1 through the second fluid pipeline 6 connected between the cleaning tank 1 and the ion exchange resin column 2. Accordingly, the surfactant that is deprotonated has an ability to clean the acidic residues remaining on the surface of the circuit board B. In addition, the addition of the liquid water is used to stabilize the deprotonation process of the surfactant, and assist in regulating the pH value of the cleaning liquid L.

The filter unit 4 is disposed on the first fluid pipeline 5 connected between the cleaning tank 1 and the ion exchange resin column 2. That is, both the filter unit 4 and the pump unit 3 are disposed on the first fluid pipeline 5. The filter unit 4 is configured to filter the cleaning liquid L from the cleaning tank 1 to remove impurities in the cleaning liquid L.

In the present embodiment, the filter unit 4 is disposed between the ion exchange resin column 2 and the pump unit 3, but the present disclosure is not limited thereto. For example, the filter unit 4 can also be disposed between the cleaning tank 1 and the pump unit 3.

The cleaning liquid in the related art adopts amine compounds for providing the cleaning ability to clean acidic residues remaining on the surface of the circuit board, so that the problem of the amine compounds remaining on the surface of the circuit board may easily occur. Comparatively, the circuit board cleaning system of the present disclosure is an innovative cleaning system that includes the basic ion exchange resin, the hydrocarbon-based surfactant, and the liquid water. The circuit board cleaning system of the present disclosure can adjust a cleaning ability by deprotonation of the hydrocarbon-based surfactant through the basic ion exchange resin, thereby cleaning the acidic residues remaining on the surface of the circuit board. Since the cleaning liquid of the circuit board cleaning system of the present disclosure does not adopt amine compounds, the amine compounds will not remain on the surface of the circuit board during the cleaning process, so as to resolve the problem of insufficient stacking adhesion strength caused thereby in subsequent processes.

### Second Embodiment

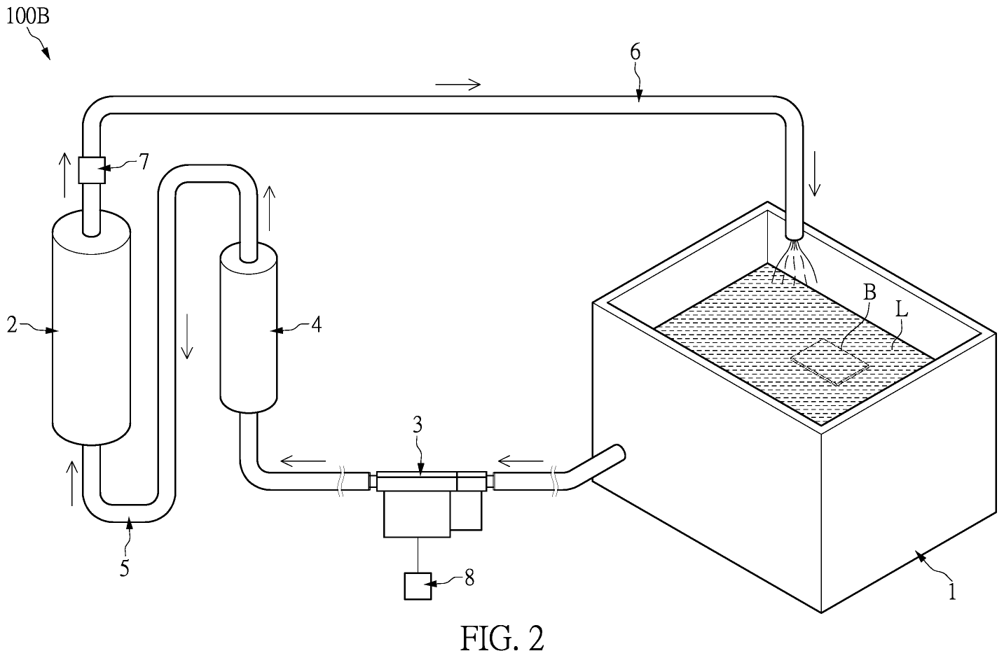

Referring to FIG. 2, a second embodiment of the present disclosure also provides a circuit board cleaning system 100B. The circuit board cleaning system 100B of the present embodiment is substantially the same as the above-mentioned first embodiment. The difference is that the circuit board cleaning system 100B of the present embodiment further includes: a pH monitoring unit 7 and a flow rate control unit 8. The pH monitoring unit 7 is disposed at an outlet end of the ion exchange resin column 2, and the flow rate control unit 8 is disposed on the pump unit 3.

The pH monitoring unit 7 is configured to monitor the pH value of the cleaning liquid L that is deprotonated by the ion exchange resin column 2. The flow rate control unit 8 is configured to adjust a flow rate of the cleaning liquid L in the first fluid pipeline 5 through the pump unit 3 according to the pH value monitored by the pH monitoring unit 7, so as to adjust a residence time of the cleaning liquid L in the ion exchange resin column 2. Accordingly, the cleaning liquid L can maintain a good cleaning ability for the acidic residues remaining on the surface of the circuit board B.

For example, when the pH value of the cleaning liquid L decreases, the cleaning ability of the cleaning liquid L is weakened. Accordingly, the flow rate of the cleaning liquid L needs to be slowed down, so that the residence time of the cleaning liquid L in the ion exchange resin column 2 becomes longer, and the cleaning liquid L deprotonated by the ion-exchange resin column 2 can have an ideal pH value, so as to maintain good cleaning performance for the acidic residues remaining on the surface of the circuit board B.

In addition, interfaces of different circuit boards may require different cleaning capabilities. The circuit board cleaning system 100B of the present embodiment can adjust the cleaning ability of the cleaning liquid L according to the cleaning interface of different circuit boards by adjusting the flow rate of the pump unit 3, so that the cleaning liquid L can avoid damage to the cleaning interface, and can remove acid residues on the surface of the circuit board B.

In addition, it is worth mentioning that the circuit board cleaning system 100B of the present embodiment has a relatively long-lasting cleaning capability for the acidic residues remaining on the surface of the circuit board B. When the cleaning ability of the cleaning liquid L decreases, the ion exchange resin can simply be replaced, without needing to completely replace the cleaning liquid L in the cleaning tank 1, so that both a cleaning procedure and a maintenance procedure of the circuit board cleaning system 100B of the present embodiment are kept simple.

### Third Embodiment

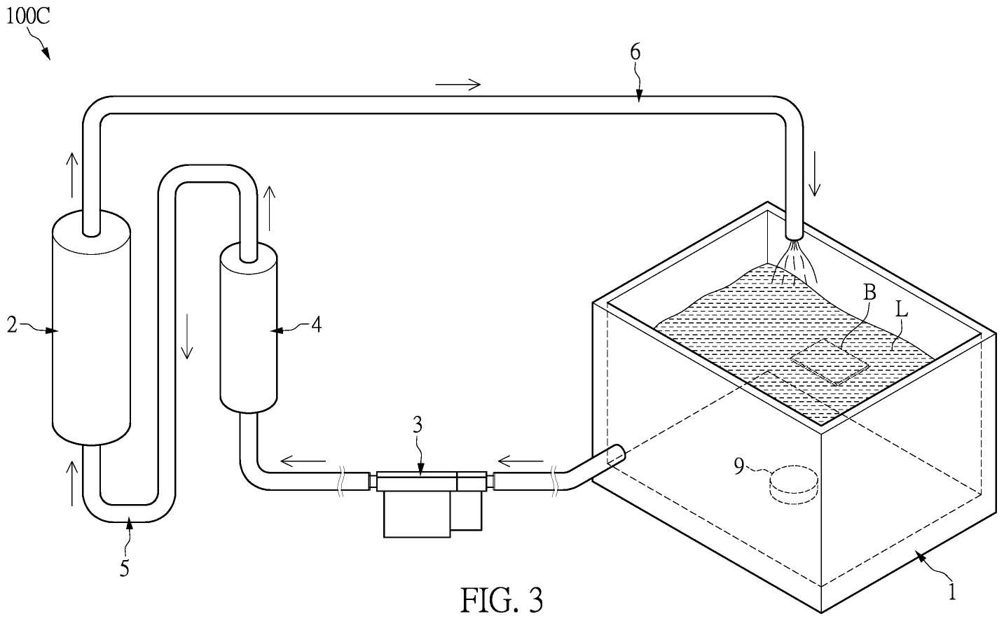

Referring to FIG. 3, a third embodiment of the present disclosure also provides a circuit board cleaning system 100C. The circuit board cleaning system 100C of the present embodiment is substantially the same as the above-mentioned first embodiment. The difference is that the circuit board cleaning system 100C of the present embodiment further includes: an ultrasonic vibration unit 9 being disposed on the cleaning tank 1. The ultrasonic vibration unit 9 is configured to oscillate the cleaning liquid L accommodated in the cleaning tank 1, so as to improve the cleaning ability of the cleaning liquid L to the acidic residues remaining on the surface of the circuit board.

### Fourth Embodiment

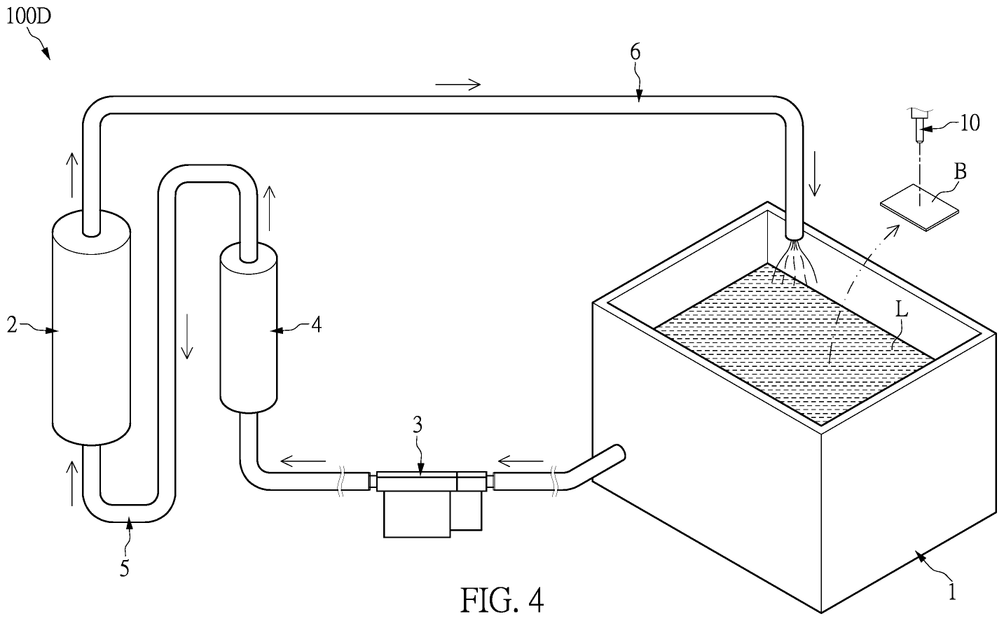

Referring to FIG. 4, a fourth embodiment of the present disclosure also provides a circuit board cleaning system 100D. The circuit board cleaning system 100D of the present embodiment is substantially the same as the above-mentioned first embodiment. The difference is that the circuit board cleaning system 100D of the present embodiment further includes: a detection unit 10.

The detection unit 10 is a micro-infrared spectrometer (FTIR-Microscope, Micro-FTIR). After the cleaning liquid L cleans the surface of the circuit board B, the detection unit 10 is configured to detect an absorption peak of a C═O functional group on the surface of the circuit board B. The absorption peak of the C═O functional group is about 1680-1735 cm⁻¹.

In the present embodiment, when the detection unit 10 detects that the absorption peak of the C═O functional group on the surface of the circuit board B completely or near-completely disappears, the circuit board cleaning system 100D determines that the cleaning process to the acidic residue remaining on the surface of the circuit board is completed.

It should be noted that, in the present embodiment, the detection method of using the detection unit 10 to detect the absorption peak of the C═O functional group on the surface of the circuit board B is as follows: the circuit board B before or after cleaning is placed at a fiber probe of an attenuated total reflection spectrometer (ATR) for analysis. A sample of the circuit board B needs to be placed on the ATR throughout the entire inspection process, and no sample pretreatment process to the sample is required. After the analysis is started, the infrared spectrum on the surface of the recording substrate (i.e., the circuit board B) can be read, verified, and analyzed from the spectrometer.

### EXPERIMENTAL DATA AND TEST RESULTS

Hereinafter, the content of the present disclosure will be described in detail with reference to Exemplary Examples 1 to 4 and Comparative Examples 1 and 2. However, the following Exemplary Examples 1 to 4 are only used to aid in the understanding of the present disclosure, and should not be construed as limiting the scope of the present disclosure.

<Exemplary Example 1>: A cleaning liquid including 93 wt % of diethylene glycol butyl ether and 7 wt % of ultrapure water is prepared in a cleaning tank. An anion exchange resin adopts a hydroxide type (OH−) strong basic anion exchange resin. Conditions for a cleaning procedure are that a temperature of the cleaning liquid heated in the cleaning tank is 80° C., and a flow rate of the cleaning liquid passing through an ion exchange resin column is 1 cc/min. A pH value of the cleaning liquid before passing through the ion exchange resin column is 5.4, and a pH value of the cleaning liquid after passing through the ion exchange resin column is 8.9. The cleaning condition is that a circuit board is immersed in the cleaning liquid for 3 minutes, and a removal rate of a C═O functional group on a surface of the circuit board analyzed by FT-IR (i.e., a removal ratio (%) of 1680-1735 cm⁻¹) is 100%.

<Exemplary Example 2>: A cleaning liquid including 93 wt % of diethylene glycol butyl ether and 7 wt % of ultrapure water is prepared in a cleaning tank. An anion exchange resin adopts a hydroxide type (OH−) strong basic anion exchange resin. Conditions for a cleaning procedure are that a temperature of the cleaning liquid heated in the cleaning tank is 80° C., and a flow rate of the cleaning liquid passing through an ion exchange resin column is 1.5 cc/min. A pH value of the cleaning liquid before passing through the ion exchange resin column is 5.4, and a pH value of the cleaning liquid after passing through the ion exchange resin column is 9.8. The cleaning condition is that a circuit board is immersed in the cleaning liquid for 3 minutes, and a removal rate of a C═O functional group on a surface of the circuit board analyzed by FT-IR (i.e., a removal ratio (%) of 1680-1735 cm⁻¹) is 100%.

<Exemplary Example 3>: A cleaning liquid including 93 wt % of diethylene glycol butyl ether and 7 wt % of ultrapure water is prepared in a cleaning tank. An anion exchange resin adopts a hydroxide type (OH−) strong basic anion exchange resin. Conditions for a cleaning procedure are that a temperature of the cleaning liquid heated in the cleaning tank is 50° C., and a flow rate of the cleaning liquid passing through an ion exchange resin column is 3.0 cc/min. A pH value of the cleaning liquid before passing through the ion exchange resin column is 5.4, and a pH value of the cleaning liquid after passing through the ion exchange resin column is 9.8. The cleaning condition is that a circuit board is immersed in the cleaning liquid for 3 minutes, and a removal rate of a C═O functional group on a surface of the circuit board analyzed by FT-IR (i.e., a removal ratio (%) of 1680-1735 cm⁻¹) is 100%.

<Exemplary Example 4>: A cleaning liquid including 93 wt % of diethylene glycol butyl ether and 7 wt % of ultrapure water is prepared in a cleaning tank. An anion exchange resin adopts a hydroxide type (OH−) strong basic anion exchange resin. Conditions for a cleaning procedure are that a temperature of the cleaning liquid heated in the cleaning tank is 50° C., and a flow rate of the cleaning liquid passing through an ion exchange resin column is 2.0 cc/min. A pH value of the cleaning liquid before passing through the ion exchange resin column is 5.4, and a pH value of the cleaning liquid after passing through the ion exchange resin column is 8.0. The cleaning condition is that a circuit board is immersed in the cleaning liquid for 3 minutes, and a removal rate of a C═O functional group on a surface of the circuit board analyzed by FT-IR (i.e., a removal ratio (%) of 1680-1735 cm⁻¹) is 74%.

<Comparative Example 1>: A cleaning liquid including 90 wt % of diethylene glycol butyl ether and 10 wt % of ultrapure water is prepared in a cleaning tank. An anion exchange resin adopts a weakly basic anion exchange resin. Conditions for a cleaning procedure are that a temperature of the cleaning liquid heated in the cleaning tank is 80° C., and a flow rate of the cleaning liquid passing through an ion exchange resin column is 1.0 cc/min. A pH value of the cleaning liquid before passing through the ion exchange resin column is 5.5, and a pH value of the cleaning liquid after passing through the ion exchange resin column is 7.3. The cleaning condition is that a circuit board is immersed in the cleaning liquid for 3 minutes, and a removal rate of a C═O functional group on a surface of the circuit board analyzed by FT-IR (i.e., a removal ratio (%) of 1680-1735 cm⁻¹) is merely 27%.

<Comparative Example 2>: A cleaning liquid including 90 wt % of diethylene glycol butyl ether and 10 wt % of ultrapure water is prepared in a cleaning tank. An anion exchange resin adopts a weakly basic anion exchange resin. Conditions for a cleaning procedure are that a temperature of the cleaning liquid heated in the cleaning tank is 80° C., and a flow rate of the cleaning liquid passing through an ion exchange resin column is 0.5 cc/min. A pH value of the cleaning liquid before passing through the ion exchange resin column is 5.5, and a pH value of the cleaning liquid after passing through the ion exchange resin column is 7.7. The cleaning condition is that a circuit board is immersed in the cleaning liquid for 3 minutes, and a removal rate of a C═O functional group on a surface of the circuit board analyzed by FT-IR (i.e., a removal ratio (%) of 1680-1735 cm⁻¹) is merely 33%.

The experimental data show that the cleaning conditions of Exemplary Examples 1 to 4 result in better removal rates of the C═O functional group (acidic substances) on the circuit boards.

TABLE

| | | Exemplary | Exemplary | Exemplary | Exemplary | Comparative | Comparative |
|---|---|---|---|---|---|---|---|
| | | Example 1 | Example 2 | Example 3 | Example 4 | Example 1 | Example 2 |
| composition of | diethylene | 93 wt % | 93 wt % | 93 wt % | 93 wt % | 90 wt % | 90 wt % |
| cleaning liquid | glycol butyl | | | | | | |
| | ether | | | | | | |
| | ultrapure | 7 wt % | 7 wt % | 7 wt % | 7 wt % | 10 wt % | 10 wt % |
| | water | | | | | | |
| type of anion | weak base | — | — | — | — | ⊚ | ⊚ |
| exchange resin | strong base | ⊚ | ⊚ | ⊚ | ⊚ | — | — |
| conditions for | temperature | 80 | 80 | 50 | 50 | 80 | 80 |
| cleaning | of cleaning | | | | | | |
| procedure | liquid (° C.) | | | | | | |
| | flow rate of | 1.0 | 1.5 | 3.0 | 2.0 | 1.0 | 0.5 |
| | cleaning | | | | | | |
| | liquid passing | | | | | | |
| | through | | | | | | |
| | column | | | | | | |
| | (cc/min) | | | | | | |
| pH value of | before | 5.4 | 5.4 | 5.4 | 5.4 | 5.5 | 5.5 |
| cleaning liquid | treatment | | | | | | |
| | after | 8.9 | 9.8 | 9.8 | 8.0 | 7.3 | 7.7 |
| | treatment | | | | | | |
| removal rate of | removal ratio | 100% | 100% | 100% | 74% | 27% | 33% |
| C═O functional | (%) of 1680- | | | | | | |
| group on surface | 1735 cm⁻¹ | | | | | | |
| of circuit board | | | | | | | |
| analyzed by FT- | | | | | | | |
| IR (circuit board | | | | | | | |
| immersed in | | | | | | | |
| cleaning liquid | | | | | | | |
| for 3 minutes) | | | | | | | |

### BENEFICIAL EFFECTS OF THE EMBODIMENTS

In conclusion, the circuit board cleaning system of the present disclosure is an innovative cleaning system that includes the basic ion exchange resin, the hydrocarbon-based surfactant, and the liquid water. The circuit board cleaning system of the present disclosure can adjust a cleaning ability by deprotonation of the hydrocarbon-based surfactant through the basic ion exchange resin, thereby cleaning the acidic residues remaining on the surface of the circuit board. Since the cleaning liquid of the circuit board cleaning system does not adopt amine compounds, the amine compounds will not remain on the surface of the circuit board during the cleaning process, so as to resolve the problem of insufficient stacking adhesion strength in the subsequent process.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit board cleaning system, comprising:
a cleaning tank configured to accommodate a cleaning liquid; wherein the cleaning tank allows a circuit board to be immersed in the cleaning liquid during a cleaning process, and the cleaning liquid includes liquid water and a hydrocarbon-based surfactant;
an ion exchange resin column located at a side of the cleaning tank; wherein an ion exchange resin filled in the ion exchange resin column is a basic ion exchange resin; and
a pump unit located between the cleaning tank and the ion exchange resin column; wherein the pump unit is configured to pump the cleaning liquid accommodated in the cleaning tank into the ion exchange resin column via a first fluid pipeline, and enable the cleaning liquid to pass through the ion exchange resin column;
wherein, when the cleaning liquid passes through the ion exchange resin column, the basic ion exchange resin deprotonates the hydrocarbon-based surfactant, and increases a pH value of the cleaning liquid to be between 8 and 11;
wherein, after the cleaning liquid passes through the ion exchange resin column, the circuit board cleaning system further returns the cleaning liquid to the cleaning tank via a second fluid pipeline, so that the hydrocarbon-based surfactant that is deprotonated is capable of removing an acidic residue remaining on a surface of the circuit board.

2. The circuit board cleaning system according to claim 1, wherein, in the cleaning liquid, the hydrocarbon-based surfactant is a nonionic surfactant having a chemical structural formula of: R₁—O—[(CH₂CH(R₂)—O)ₓ(CH₂CH₂O)_{y}]_{z}—H; wherein x is 0 or a real number between 1 and 5 at each independent occurrence thereof, provided that at least one occurrence of x is greater than 0; y is 0 or a real number between 1 and 11 at each independent occurrence thereof, provided that at least one occurrence of y is greater than 0; z is an integer between 1 and 50; R₁ is a branched or straight chain alkyl group having a carbon chain length of C1-C12; and R₂ is CH₃ or CH₂CH₃ at each independent occurrence thereof.

3. The circuit board cleaning system according to claim 1, wherein, in the cleaning liquid, the hydrocarbon-based surfactant is diethylene glycol butyl ether, and the diethylene glycol butyl ether has a chemical structural formula of: HO(CH₂)₂O(CH₂)₂O(CH₂)₃CH₃.

4. The circuit board cleaning system according to claim 1, wherein, in the cleaning liquid, a content of the hydrocarbon-based surfactant is between 80% (V/V) and 95% (V/V), and a content of the liquid water is between 5% (V/V) and 20% % (V/V).

5. The circuit board cleaning system according to claim 1, wherein the ion exchange resin filled in the ion exchange resin column is a hydroxide strong basic anion exchange resin.

6. The circuit board cleaning system according to claim 1, further comprising: a pH monitoring unit being disposed at an outlet end of the ion exchange resin column and a flow rate control unit being disposed on the pump unit; wherein the pH monitoring unit is configured to monitor the pH value of the cleaning liquid that is deprotonated by the ion exchange resin column; wherein the flow rate control unit is configured to adjust a flow rate of the cleaning liquid in the first fluid pipeline through the pump unit according to the pH value monitored by the pH monitoring unit, so as to adjust a residence time of the cleaning liquid in the ion exchange resin column.

7. The circuit board cleaning system according to claim 1, further comprising: an ultrasonic vibration unit being disposed on the cleaning tank; wherein the ultrasonic vibration unit is configured to oscillate the cleaning liquid accommodated in the cleaning tank.

8. The circuit board cleaning system according to claim 1, further comprising: a detection unit; wherein the detection unit is configured to detect an absorption peak of a C═O functional group on the surface of the circuit board; wherein, when the detection unit detects that the absorption peak of the C═O functional group on the surface of the circuit board completely or near-completely disappears, the circuit board cleaning system determines that the cleaning process to the acidic residue remaining on the surface of the circuit board is completed.

9. The circuit board cleaning system according to claim 1, further comprising: a filter unit being disposed on the first fluid pipeline that is connected between the cleaning tank and the ion exchange resin column; wherein the filter unit is configured to filter the cleaning liquid from the cleaning tank to remove impurities in the cleaning liquid.

10. The circuit board cleaning system according to claim 1, wherein a resin filling amount of the ion exchange resin column is packing 50 to 150 grams of the ion exchange resin into a column of 120 to 180 cubic centimeters; wherein a flow rate of the cleaning liquid that passes through the ion exchange resin column is between 0.5 cubic centimeters and 3 cubic centimeters per minute.
